(19) United States
(12) Patent Application Publication
(10) Pub. No.: US 2009/0001433 A1
(43) Pub. Date: Jan. 1, 2009

(54) Image Sensor and Method for Manufacturing the Same

(76) Inventor: Joo Hyun LEE, Icheon-si (KR)

Correspondence Address: THE LAW OFFICES OF ANDREW D. FORTNEY, PH.D., P.C., 401 W FALLBROOK AVE STE 204, FRESNO, CA, 93711-5835, US

(21) Appl. No.: 12/145,335

(22) Filed: Jun. 24, 2008

(30) Foreign Application Priority Data
Jun. 26, 2007 (KR) 10-2007-0062679

(51) Int. Cl. H01L 31/113; H01L 21/00; H01L 21/425

(52) U.S. Cl. 257/291; 438/73; 438/514; 257/E27.13

(57) ABSTRACT

Provided are an image sensor and a method of fabricating the same. The image sensor includes a substrate having an active area and a device isolation area; a well implantation area in the active area; a threshold voltage implantation area in the well implantation area; and a transistor gate on the threshold voltage implantation area, wherein the threshold voltage implantation has a width greater than a width of the transistor gate.

### CROSS-REFERENCE TO RELATED APPLICATIONS

The present application claims the benefit under 35 U.S.C. §119 of Korean Patent Application No. 10-2007-0062679, filed Jun. 26, 2007, which is hereby incorporated by reference in its entirety.

### BACKGROUND

A complementary metal oxide silicon (CMOS) image sensor is a device for converting electrons, caused by light incident to a photodiode, into a voltage. The electrons generated in the photodiode are transferred through a transfer transistor Tx in a case of a 4Tr type, or a reset transistor Rx in a case of a 3Tr type (see, e.g., FIG. 9). Additionally, transfer characteristic of electrons change according to types of these transistors.

Herein, an exemplary circuit and layout for the unit pixel of a 4Tr type CMOS image sensor will be described.

FIG. 7 is a circuit view of a 4Tr type CMOS image sensor of the related art, and FIG. 2 is a layout showing a unit pixel of a 4Tr type CMOS image sensor of the related art.

As shown in FIGS. 7 and 8, a unit pixel 100 of a CMOS image sensor comprises a photodiode 10 and four transistors. The four transistors are a transfer transistor 20, a reset transistor 30, a drive transistor 40, and a select transistor 50, respectively. A load transistor 60 may be electrically connected to the output terminal OUT of the respective unit pixels 100.

A device isolating layer (not shown) is formed in a semiconductor substrate by a STI (Shallow Trench Isolation) or LOCOS process in a portion of the substrate other than the active area (which is shown in FIG. 8). The device isolating layer defines an active area, wherein the active area includes the active areas of the four transistors. Herein, FD represents a floating diffusion area, Tx represents the gate of the transfer transistor 20, Rx represents the gate of the reset transistor 30, Dx represents the gate of the drive transistor 40, and Sx represents the gate of the select transistor 50.

A photodiode PD is formed in a portion of the active area having a relatively wide width, and the gate electrodes 23, 33, 43, and 53 of the four transistors are formed in another portion of the active area. In other words, a transfer transistor 20 is formed using the gate electrode 23, a reset transistor 30 is formed using the gate electrode 33, a drive transistor 40 is formed using the gate electrode 43, and a select transistor 50 is formed using the gate electrode 53. Herein, the active areas of the respective transistors (excluding the channel regions under the respective gate electrodes 23, 33, 43, and 53) are implanted with impurity ions so that source/drain (S/D) areas of the respective transistors are formed.

In the related art image sensor, the yield loss can be serious. This yield loss may be classified into function failures and signal failures.

### SUMMARY

Embodiments of the invention provide an image sensor capable of being obtained in a stable yield by attaining and/or identifying a process factor that deals with signal failures and controlling the process factor, and a method of fabricating such image sensors.

In one embodiment, an image sensor may comprise a substrate having an active area and a device isolation area; a well implantation area in the active area; a threshold voltage implantation area in the well implantation area; and a transistor gate on the threshold voltage implantation area, wherein the threshold voltage implantation area is broader than an area of the transistor. For example, the threshold voltage implantation area may have a first width, and transistor gate may have a second width smaller than the first width.

In another embodiment, a method of fabricating an image sensor may comprise defining an active area and a device isolation area in a substrate of the image sensor; forming a well implantation area in the active area; forming a threshold voltage implantation area by performing threshold implantation (e.g., implanting ions of a conductivity type, in a dose and/or at an energy sufficient to adjust and/or control a threshold voltage of a transistor) in the well implantation area; and forming a transistor gate on the threshold voltage implantation area, wherein the threshold voltage implantation area is broader than an area of the transistor.

The details of one or more embodiments are set forth in the accompanying drawings and the description below. Other features will be apparent from the description and drawings, and from the claims.

### BRIEF DESCRIPTION OF THE DRAWINGS

FIGS. 1 and 2 are views illustrating a first exemplary image sensor and a method of fabricating the same.

FIGS. 3 and 4 are views illustrating a second exemplary image sensor and a method of fabricating the same.

FIGS. 5 and 6 are views illustrating a third exemplary image sensor and a method of fabricating the same.

### DETAILED DESCRIPTION OF THE EMBODIMENTS

Hereinafter, image sensors according to various embodiments and methods of fabricating the same will be described with reference to the accompanying drawings.

Embodiments may be applied to a 3Tr image sensor including one photodiode and three transistors (a reset transistor, a drive transistor, and a select transistor; see FIG. 9) and a 4Tr image sensor including one photodiode and four transistors (a transfer transistor, a reset transistor, a drive transistor, and a select transistor; see FIGS. 7-8).

### First Embodiment

The yield loss for an image sensor can be serious. Yield losses of a certain type can be classified into function failures and signal failures.

Embodiments of the invention provide an image sensor capable of being obtained in a stable yield by searching, determining and/or identifying a process factor that manages or affects signal failures and controlling the process factor(s), and a method of fabricating such image sensors. Accordingly, embodiments of the invention confirm and/or identify a process management or control point for obtaining a stable yield by validating that certain yield deviation occurs due to a relationship between a threshold voltage Vthi of a transistor and an overlay of the threshold voltage implantation mask (e.g., relative to the location of the transistor gate mask) during implantation. For example, a relationship between the threshold voltage implantation mask overlay and the threshold voltage Vthi of a reset transistor has been validated.

In various embodiments, threshold voltage implantation is a process a threshold voltage Vth of a transistor (e.g., the reset transistor in a CMOS image sensor) can be adjusted, controlled and/or determined. In general, threshold voltage implantation may be performed at a low energy and a low dosage. Threshold voltage implantation generally determines the voltage (threshold voltage Vth) at which a transistor is turned on and/or off.

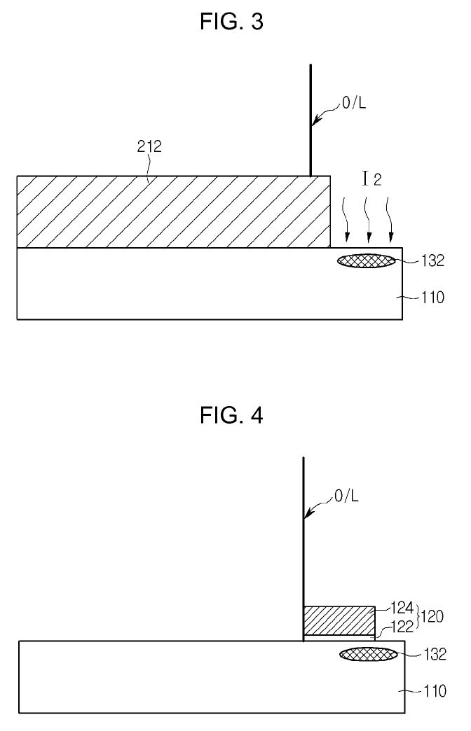

For example, under certain conditions, the threshold voltage Vth is about 0.15 V in a reset transistor 120 (see FIGS. 2, 4 and 6; see also transistor Rx 30 in FIG. 7 and transistor Rx in FIG. 9), but is not limited thereto. On the other hand, the actual operating voltage is generally a relatively high voltage, but not so high that the gate insulation layer or other part of the transistor (e.g., the gate) is damaged.

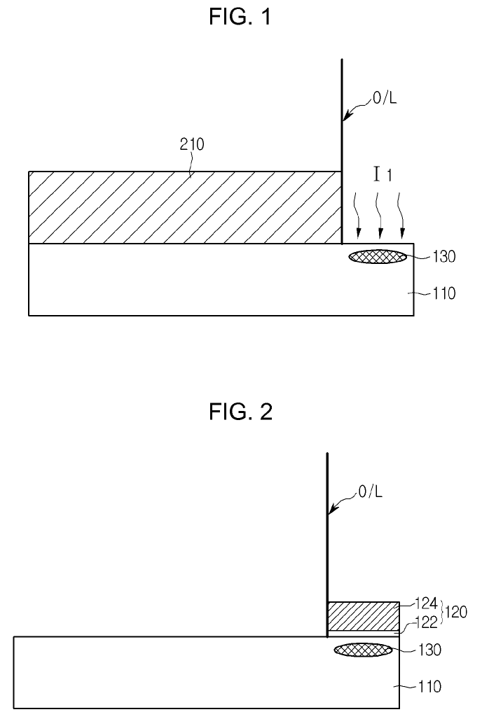

FIGS. 1 and 2 are views of threshold implantation processes according to a first method.

That is, forming a first threshold voltage implantation area 130 includes forming a first threshold implantation pattern 210 without any margin from an area where a transistor gate 120 (see FIG. 2) is to be formed. In other words, the width of the first threshold voltage implantation area 130 is not greater than the width of the transistor gate electrode 122, and the overlay between the threshold voltage implant mask and the transistor gate mask is substantially the same, within alignment tolerances. For example, forming the first threshold voltage implantation area 130 may include forming the first threshold implantation pattern 210 at a position where an overlay position O/L is zero.

At this point, an active area (not shown) and a device isolation area (not shown) are defined in the substrate 110, and a well implantation area (not shown) may be further formed in the active area. Preferably, the well implantation area encompasses the entire transistor area, and is formed before the first threshold voltage implantation area 130. Then, first threshold implantation I1 is performed using the first threshold implantation pattern 210 as an implantation mask.

Next, as illustrated in FIG. 2, the transistor 120 is formed on the first threshold voltage implantation area 130. The transistor 120 includes a gate insulation layer 122 and a gate electrode 124. For example, the transistor 120 may be a reset transistor, but is not limited thereto. Lightly doped source/drain extensions (not shown) and source and drain terminals (e.g., the outlined areas between gates 23, 33, 43 and 53 in FIG. 2) are generally formed after formation of the first threshold voltage implantation area 130.

However, as illustrated in FIG. 2, because the first threshold voltage implantation area 130 is designed to be adjacent to (and preferably completely below) the transistor gate 120, there is no margin between the transistor 120 and the first threshold implantation pattern 210. For example, as illustrated in FIG. 1, the first threshold voltage implantation pattern 210 is formed on a position where overlay position O/L is zero.

Due to this design, an overlay of the threshold implantation is very important, and an overlay target may be managed with a reasonable value (about ±0.10 μm or less) through an overlay split test.

To validate effectiveness according to a threshold implantation post engraving pattern (PEP) overlay, changes in the threshold voltage Vth and yield under current conditions (the first method) through a shift of ±0.05 μm and ±0.10 μm are confirmed (see the results in Tables 1 and 2 below).

### Second Method

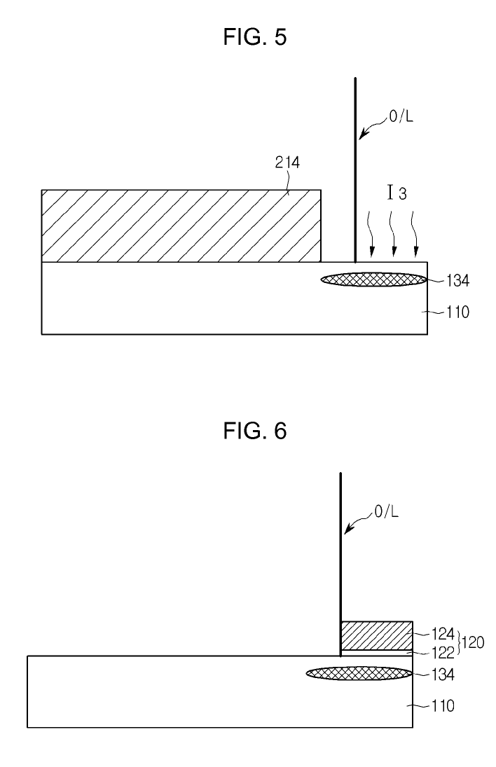

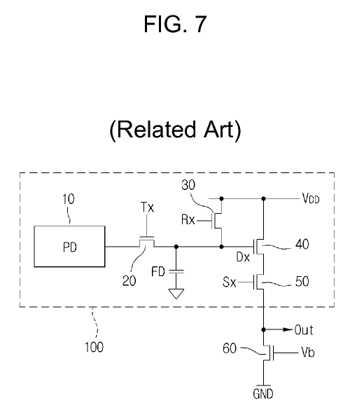

FIGS. 3 and 4 are views when threshold implantation is performed according to a second method. According to the second method, changes in a threshold voltage Vth and a yield of a reset transistor are confirmed through a shift of ±0.05 μm and ±0.10 μm, unlike the first method.

That is, according to the second method as illustrated in FIG. 3, forming a second threshold voltage implantation area 132 includes forming a second threshold implantation pattern 212 in the right direction (+ direction) with margin from (or relative to) an area where a transistor gate 120 is formed. For example, forming the second threshold voltage implantation area 132 may include forming a second threshold implantation pattern 212 that is shifted toward the right (+ direction) from a position where an overlay position O/L is zero. When the transistor is a reset transistor, the direction of the overlay shift may be towards the source/drain terminal of the reset transistor that is connected to a power supply (e.g., Vdd in FIG. 7, the active region between gates 33 and 43 in FIG. 8, or V_{R} in FIG. 9).

At this point, an active area (not shown) and a device isolation area (not shown) are defined in the substrate 110, and a well implantation area (not shown) may be further formed in the active area, as discussed above.

Then, a threshold voltage implantation I2 is performed, using the second threshold voltage implantation pattern 212 as an implantation mask, to form a second threshold voltage implantation area 132. The dose, energy and ion conductivity type is generally the same as described above. The width of the second threshold voltage implantation pattern 212 may be substantially the same as or less than the width of the transistor gate electrode 122, within alignment tolerances, but the offset of the threshold voltage implantation pattern 212 from the corresponding pattern for the transistor gate mask may result in the transistor gate 124 only partially overlapping threshold voltage implantation area 132.

Next, as illustrated in FIG. 4, a transistor gate 120 is formed on the second threshold voltage implantation area 132. The transistor gate 120 includes a gate insulation layer 122 and a gate electrode 124. For example, the transistor gate 120 may be a reset transistor, but is not limited thereto. Lightly doped source/drain extensions (not shown) and source and drain terminals are generally formed after formation of the second threshold voltage implantation area 212, similar to the description above.

### Third Method

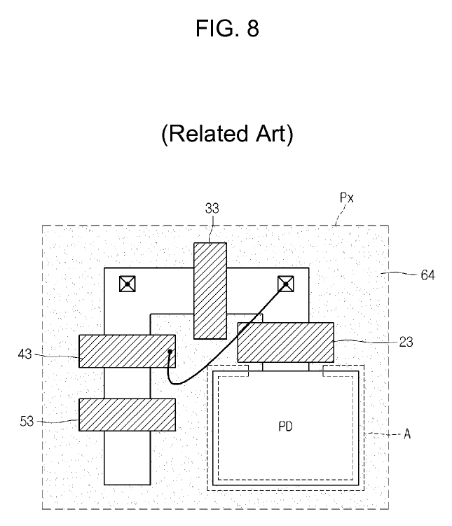

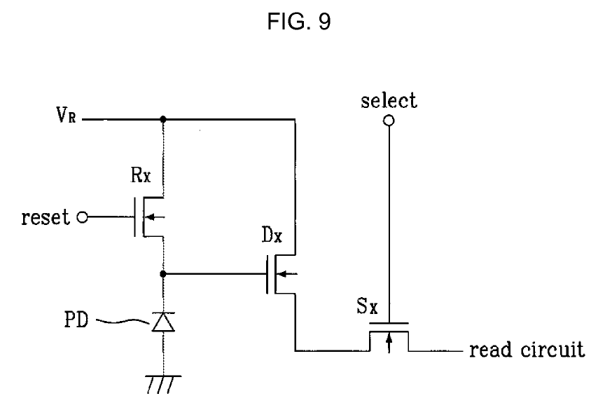

Next, FIGS. 5 and 6 are views when threshold implantation is performed according to a third method. According to the third method, changes in the threshold voltage Vth and yield of the reset transistor are confirmed through a shift of −0.05 μM and −0.10 μm, unlike the first method.

That is, according to the third method as illustrated in FIG. 5, forming a third threshold voltage implantation area 134 includes forming a third threshold implantation pattern 214 in the left (−) direction, with a margin from the area where the transistor gate 120 is formed. For example, forming the third threshold voltage implantation area 134 includes forming a third threshold implantation pattern 214 that is shifted toward the left (−) direction from a position where an overlay position O/L is zero. When the transistor is a reset transistor in a 4Tr unit pixel (FIGS. 7-8), the direction of the overlay shift may be towards the floating diffusion region (e.g., FD in FIG. 7 and the active region between gates 23 and 33 in FIG. 8). When the transistor is a reset transistor in a 3Tr unit pixel (FIG. 9), the direction of the overlay shift may be towards the photodiode (see, e.g., PD in FIG. 8; the 3Tr unit cell generally does not include a transfer transistor Tx as shown in FIG. 7).

At this point, an active area (not shown) and a device isolation area (not shown) are defined in the substrate 110, and a well implantation area (not shown) may be further formed in the active area. Then, a threshold voltage implantation I3 is performed using the third threshold implantation pattern 214 as an implantation mask.

Next, as illustrated in FIG. 6, a transistor gate 120 is formed on the third threshold voltage implantation area 134. The transistor gate 120 includes a gate insulation layer 122 and a gate electrode 124. For example, the transistor 120 may be a reset transistor, but it is not limited thereto. Lightly doped source/drain extensions (not shown) and source and drain terminals are generally formed after formation of the third threshold voltage implantation area 214, similar to the description above.

Thus, in various embodiments, the third threshold voltage implantation area 214 may have a width that is greater than the width of the transistor gate electrode 124, and there may be substantially complete overlap between the threshold voltage implantation area and the transistor gate.

### Experimental Result

TABLE 1

| | | | First Method | Second | |
|---|---|---|---|---|---|
| | Third Method (Left) | | (Target) | method (Right) | |
| Condition | −0.10 μm | −0.05 μm | 0.00 μm | +0.05 μm | +0.10 μm |
| Average | 0.161 | 0.148 | 0.140 | 0.114 | 0.086 |
| Standard | 0.018 | 0.013 | 0.015 | 0.029 | 0.034 |
| Deviation | | | | | |

Table 1 is a measurement result according to an overlay split of the threshold voltage implantation patterns of FIGS. 1, 3 and 5.

According to the first method, when the threshold voltage implantation pattern is formed without margin with respect to the reset transistor gate area, the threshold voltage Vth is about 0.14 V (which is lower than expected, 0.15 V).

On the other hand, according to the second method, when the threshold voltage implantation pattern is formed with margin in the + direction (right) with respect to the reset transistor gate area, the threshold voltage Vth is 0.114 V (+0.05 μm) or 0.086 V (+0.10 μm), both of which are much lower than expected (0.15 V).

However, according to the third method, when the threshold voltage implantation pattern is formed with margin in the − direction (left) with respect to the reset transistor gate area, the threshold voltage Vth is 0.148 V (−0.05 μm) or 0.161 V (+0.10 μm), both of which are very close to the expected value (0.15 V).

As a result, when a threshold implantation pattern is formed with a margin in the (−) direction (left) with respect to the reset transistor gate area, an optimized threshold voltage can be achieved, and also as shown in the standard deviation result, reliability becomes excellent compared to when the margin is in the (+) direction.

TABLE 2

| | | | First Method | Second Method | |
|---|---|---|---|---|---|
| | Third Method (Left) | | (Target) | (Right) | |
| Yield (%) | −0.10 μm | −0.05 μm | 0.00 μm | +0.05 μm | +0.10 μm |
| Average | 73.40 | 76.88 | 71.65 | 27.11 | 0.00 |
| Max | 75.88 | 77.32 | 82.52 | 27.99 | 0.00 |
| Min | 70.91 | 76.44 | 59.18 | 26.22 | 0.00 |

Table 2 is a yield measurement result according to an overlay split of the threshold implantation pattern of FIGS. 1, 3 and 5.

As shown in Table 2, according to the first method, when the threshold voltage implantation pattern is formed without margin with respect to the reset transistor gate, its average yield is about 71.65%.

On the other hand, according to the second method, when the threshold voltage implantation pattern is formed in a + direction (right) with margin with respect to the reset transistor gate area, the average yield is about 0.00% to about 27.11%, which is unacceptably low.

However, according to the third method, when the threshold voltage implantation pattern is formed in a − direction (left) with margin with respect to the reset transistor gate area, the average yield is about 73.40% to about 76.88%, which is very high. That is, when the threshold voltage implantation pattern is formed in a − direction (left) with margin with respect to the reset transistor gate area, an optimized yield improvement can be achieved.

The results of Table 2 are related to the results of Table 1. That is, if the threshold voltage implantation pattern is formed in a − direction (left) with margin with respect to a reset transistor, an optimized threshold voltage Vth, designed for a corresponding device, can be achieved. If the optimized threshold voltage Vth is obtained, signal failures can be minimized such that the optimized yield improvement can be obtained.

Embodiments of the invention can reduce signal failures by adjusting an overlay of a threshold voltage implantation pattern to obtain additional margin thereof, such that the threshold voltage of one or more transistors therein (e.g., the reset transistor) can have an acceptable threshold voltage and/or an acceptable variation therein, and the image sensor can be obtained in a stable yield.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. An image sensor comprising:
a substrate having an active area and a device isolation area;
a well implantation area in the active area;
a threshold voltage implantation area in the well implantation area, the threshold voltage implantation area having a first width; and
a transistor gate on the threshold voltage implantation area, the transistor gate having a second width smaller than the first width.

2. The image sensor according to claim 1, wherein the transistor gate is a reset transistor gate.

3. The image sensor according to claim 1, wherein the transistor gate completely overlaps the threshold voltage implantation area.

4. The image sensor according to claim 1, wherein the threshold voltage implantation area extends towards (i) a floating diffusion region or (ii) a photodiode region.

5. The image sensor according to claim 4, wherein the threshold voltage implantation area is substantially aligned with the transistor gate sidewall closest to a source/drain terminal connected to a power supply.

6. The image sensor according to claim 1, further comprising source and drain terminals on opposite sides of the threshold voltage implantation area.

7. The image sensor according to claim 1, wherein the transistor gate comprises a gate dielectric layer on the substrate above the threshold voltage implantation area and a transistor gate electrode on the gate dielectric layer.

8. The image sensor according to claim 1, wherein the threshold voltage implantation area comprises ions of a conductivity type, in a dose and at an energy sufficient to adjust and/or control a threshold voltage of a transistor including the transistor gate.

9. A method of fabricating an image sensor, the method comprising:
defining an active area and a device isolation area in a substrate;
forming a well implantation area in the active area;
forming a threshold voltage implantation area implantation ions in the well implantation area, the threshold voltage implantation area having a first width; and
forming a transistor having a second width on the threshold voltage implantation area, wherein the first width is greater than the second width.

10. The method according to claim 9, wherein forming the threshold voltage implantation area comprises:
forming a threshold voltage implantation pattern with margin from a transistor gate area; and
implanting the ions using the threshold voltage implantation pattern as a mask.

11. The method according to claim 9, wherein forming the threshold voltage implantation area comprises:
forming a threshold voltage implantation pattern by shifting toward a minus(−) direction from a point where an overlay position is zero; and
implanting the ions using the threshold voltage implantation pattern as an implantation mask.

12. The method according to claim 11, wherein the threshold voltage implantation pattern is shifted 0.05 μm to 0.10 μm in the minus(−) direction from the point where the overlay position is zero.

13. The method according to claim 9, wherein the threshold voltage implantation pattern has an opening aligned with a corresponding transistor gate mask pattern.

14. The method according to claim 13, wherein the opening in the threshold voltage implantation pattern is from 0.01 μm to 0.10 μm wider than the corresponding transistor gate mask pattern in a direction of (i) a floating diffusion region or (ii) a photodiode region.

15. The method according to claim 14, wherein the opening in the threshold voltage implantation pattern is substantially aligned with the corresponding transistor gate mask pattern in a direction of a source/drain terminal connected to a power supply.

16. The method according to claim 9, wherein the transistor gate comprises a reset transistor gate.

17. The method according to claim 9, wherein the ions have a conductivity type and are implanted in a dose and at an energy sufficient to adjust and/or control a threshold voltage of a transistor including the transistor gate.
